(19) United States
(12) Patent Application Publication
(10) Pub. No.: US 2021/0359275 A1
(43) Pub. Date: Nov. 18, 2021

(54) OPTICAL FILM AND DISPLAY DEVICE INCLUDING THE SAME

(71) Applicant: Samsung Display Co., LTD., Yongin-si (KR)

(72) Inventors: Beong-Hun BEON, Hwaseong-si (KR); Duk Jin LEE, Suwon-si (KR); Woo Suk JUNG, Cheonan-si (KR); Dong-Wook CHOI, Hwaseong-si (KR)

(73) Assignee: Samsung Display Co., LTD., Yongin-si (KR)

(21) Appl. No.: 17/178,588

(22) Filed: Feb. 18, 2021

(30) Foreign Application Priority Data
May 12, 2020 (KR) 10-2020-0056350

(51) Int. Cl. H01L 51/52; G02B 1/115; G02B 1/14; G02B 5/30; H01L 27/32

(52) U.S. Cl. CPC H01L 51/5281; G02B 1/115; H01L 27/3244; G02B 5/3033; H01L 27/323; G02B 1/14

(57) ABSTRACT

An optical film includes a polarizing layer including a polymer dyed with iodine, a phase-retardation layer disposed under the polarizing layer, and an inorganic barrier layer including a non-polar inorganic material. The inorganic barrier layer is disposed on at least a surface of the polarizing layer, has a water vapor transmission rate (WVTR) equal to or less than about 100 g/day·m², and has a thickness equal to or less than about 5 μm. A display device comprising the optical film is also provided.

### CROSS-REFERENCE TO RELATED APPLICATION(S)

This application claims priority to and benefits of Korean Patent Application No. 10-2020-0056350 under 35 U.S.C. § 119, filed on May 12, 2020, the entire contents of which are incorporated herein by reference.

### BACKGROUND

### 1. Technical Field

Embodiments relate to an optical film and a display device including the optical film.

### 2. Description of the Related Art

A light entering into a display panel may be reflected by an electrode, a metallic wiring or the like, and the reflected light may cause deterioration of visibility and contrast of the display device.

In order to reduce the reflected light, the display device may include a polarizer. The polarizer may include a polarizing layer and a phase-retardation layer to convert a linearly polarized light into a circularly polarized light. As a result, the reflected light exiting from the display device may be decreased.

### SUMMARY

Embodiments provide an optical film with improved reliability.

Embodiments provide a display device including the optical film.

According to an embodiment, an optical film may include a polarizing layer including a polymer dyed with iodine, a phase-retardation layer disposed under the polarizing layer, and an inorganic barrier layer including a non-polar inorganic material disposed on at least a surface of the polarizing layer. The inorganic barrier layer may have a water vapor transmission rate (WVTR) equal to or less than about 100 g/day·m², and may have a thickness equal to or less than about 5 μm.

In an embodiment, the inorganic barrier layer may include at least one of NaF, Na₃AlF₃, LiF, MgF₂, CaF₂, BaF₂, BaF₂, SiO₂, LaF₃, CeF, Al₂O₃, ZrOₓ (zirconium oxide), NbOₓ (niobium oxide), ATO (antimony tin oxide), and SiNₓ (silicon nitride).

In an embodiment, the inorganic barrier layer may include SiO₂.

In an embodiment, the inorganic barrier layer may be disposed between the polarizing layer and the phase-retardation layer.

In an embodiment, the optical film may further include a protective layer including at least one of polymethylmethacrylate, triacetylcellulose, cyclo-olefin polymer, and polyethylene terephthalate.

In an embodiment, the inorganic barrier layer may be disposed between the polarizing layer and the protective layer.

In an embodiment, the inorganic barrier layer may include a first inorganic barrier layer disposed between the polarizing layer and the phase-retardation layer, and a second inorganic barrier layer disposed between the polarizing layer and the protective layer.

In an embodiment, the optical film may further include an adhesive layer contacting the inorganic barrier layer. The adhesive layer may include an adhesive binder and a silane coupling agent.

In an embodiment, the phase retardation layer may include a first phase retardation layer that is a half wave plate, and a second phase retardation layer that is a quarter wave plate.

According to an embodiment, a display device may include a panel part including a display panel, and an optical film disposed on at least a surface of the panel part. The optical film may include a polarizing layer including a polymer dyed with iodine, a phase-retardation layer disposed under the polarizing layer, and an inorganic barrier layer including a non-polar inorganic material. The inorganic barrier layer may have a water vapor transmission rate (WVTR) equal to or less than about 100 g/day·m2, and may have a thickness equal to or less than about 5 μm.

In an embodiment, the inorganic barrier layer may include at least one of NaF, Na₃AlF₃, LiF, MgF₂, CaF₂, BaF₂, BaF₂, SiO₂, LaF₃, CeF, Al₂O₃, ZrOₓ (zirconium oxide), NbOₓ (niobium oxide), ATO (antimony tin oxide), and SiNₓ (silicon nitride).

In an embodiment, the inorganic barrier layer may include SiO₂.

In an embodiment, the optical film may further include a protective layer disposed on the polarizing layer and including at least one of polymethylmethacrylate, triacetylcellulose, cyclo-olefin polymer, and polyethylene terephthalate, and the inorganic barrier layer may be disposed between the polarizing layer and the protective layer.

In an embodiment, the inorganic barrier layer may include a first inorganic barrier layer disposed between the polarizing layer and the phase-retardation layer, and a second inorganic barrier layer disposed between the polarizing layer and the protective layer.

In an embodiment, the inorganic barrier layer may be directly disposed on the polarizing layer.

In an embodiment, the optical film may further include an adhesive layer contacting the inorganic barrier layer, and the adhesive layer may include an adhesive binder and a silane coupling agent.

In an embodiment, the display panel may include a touch-sensing part.

In an embodiment, the display panel may further include a protective window disposed on the optical film.

In an embodiment, the display panel may further include a metallic functional layer disposed between the protective window and the optical film.

In embodiment, the metallic functional layer may include at least one of a fingerprint-sensing part, a pressure-sensing part, and an antenna.

According to embodiments, migration of ions or polar solvent from an optical film including a polarizing layer may be prevented. Thus, damage to a metal pattern or a metallic function layer adjacent to the optical film may be prevented. Thus, reliability of a display device including the optical film may be improved.

### BRIEF DESCRIPTION OF THE DRAWINGS

Aspects of the embodiments of the inventive concept will be more clearly understood from the following detailed description taken in conjunction with the accompanying drawings.

FIG. 1 is a schematic cross-sectional view illustrating a display device according to an embodiment.

FIG. 2 is a schematic cross-sectional view illustrating a panel part of a display device according to an embodiment.

FIG. 3 is a schematic cross-sectional view illustrating an optical film according to an embodiment.

FIG. 4 is a perspective view illustrating a process of forming an optical film according to an embodiment.

FIG. 5 is a schematic cross-sectional view illustrating a display device according to an embodiment.

FIGS. 6 to 9 are schematic cross-sectional views illustrating optical films according to embodiments.

FIG. 10 is a schematic cross-sectional view illustrating a display device according to an embodiment.

### DETAILED DESCRIPTION OF THE EMBODIMENTS

An optical film and a display device according to embodiments of the inventive concept will be described hereinafter with reference to the accompanying drawings, in which some embodiments are shown. Features of the disclosure and methods of accomplishing the same may be understood more readily by reference to the following detailed description of embodiments and the accompanying drawings. However, the disclosure is not limited to the embodiments described below, but may be implemented in various forms.

In the embodiments, terms such as “first” and “second” are used for distinguishing one component from other components, but the components are not limited to these terms. These elements are only used to distinguish one element from another.

In the embodiments, unless clearly used otherwise, expressions in the singular number include a plural meaning.

In the embodiments, terms such as “comprises,” “comprising,” “includes,” “including,” “have,” “having,” “contains,” and/or “containing” used herein specify the presence of stated features or elements, but do not preclude the presence or addition of one or more other features or elements.

In the embodiments, when an element such as a film, area or component is referred to as being “on”, “above”, or “under” another element, it can be directly on, over, or under the other element, or intervening elements may also be present.

For convenience of description, dimensions of components in the drawings may be expanded or reduced. For example, the size and thickness of each component shown in the drawings are arbitrarily shown for convenience of description, and therefore the disclosure is not necessarily limited to those illustrated in the drawings.

In the specification, the phrase “A and/or B” may be understood to mean “A, B, or A and B.” The terms “and” and “or” may be used in the conjunctive or disjunctive sense and may be understood to be equivalent to “and/or”. Throughout the disclosure, the expression “at least one of A, B, or C” may indicate only A, only B, only C, both A and B, both A and C, both B and C, all of A, B, and C, or variations thereof.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±20%, 10%, or 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanying drawings, and the same or corresponding components will be denoted by the same reference numerals.

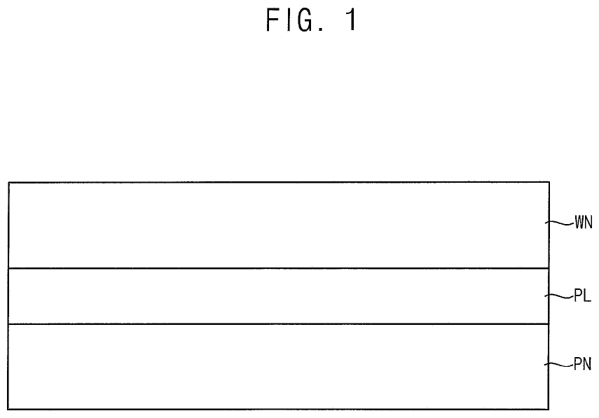

FIG. 1 is a schematic cross-sectional view illustrating a display device according to an embodiment.

Referring to FIG. 1, a display device includes a panel part PN, an optical film PL, and a protective window WN. The optical film PL may be disposed on an upper surface of the panel part PN. For example, the optical film PL may be combined with an upper surface of the panel part PN. The upper surface of the panel part PN may be a light-exiting surface, through which a light generated in the panel part PN may exit outwardly. The protective window WN may be disposed on an upper surface of the optical film PL. For example, the protective window WN may be combined with an upper surface of the optical film PL. Thus, the optical film PL may be disposed between the panel part PN and the protective window WN. The optical film PL may function as a polarizer.

An adhesive layer may be provided between the panel part PN and the optical film PL and between the optical film PL and the protective window WN to combine the panel part PN and the optical film PL with each other and to combine the optical film PL and the protective window WN with each other. For example, the adhesive layer may include an acrylic adhesive or an optically clear adhesive.

For example, the protective window WN may include glass, a polymeric material, or a combination thereof. In an embodiment, the protective window WN may include a glass thin film or a polymeric material having flexibility.

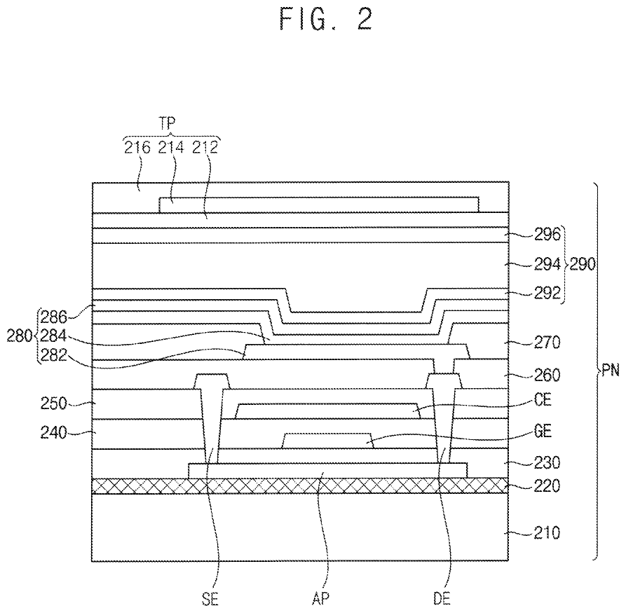

FIG. 2 is a schematic cross-sectional view illustrating a panel part of a display device according to an embodiment. The panel part may include a display panel including a pixel array. In an embodiment, the display panel may include an organic light-emitting display panel.

Referring to FIG. 2, a pixel unit of the panel part PN may include a driving element and a light-emitting element electrically connected to the driving element. In an embodiment, the light-emitting element may be an organic light-emitting diode. The driving element may include at least one thin film transistor.

In an embodiment, a buffer layer 220 may be disposed on a base substrate 210. An active pattern AP may be disposed on the buffer layer 220.

For example, the base substrate 210 may include glass, quartz, sapphire, a polymeric material, or the like. In an embodiment, the base substrate 210 may be a flexible substrate including a polymeric material. For example, the base substrate 210 may include polyethylene naphthalate, polyethylene terephthalate, polyether ketone, polycarbonate, polyarylate, polyether sulphone, polyimide, or a combination thereof.

The panel part PN may further include a supporting substrate disposed under the base substrate 210.

The buffer layer 220 may prevent or reduce permeation of impurities, humidity, or external gas from underneath of the base substrate 210, and may reduce a roughness of an upper surface of the base substrate 210. For example, the buffer layer 220 may include an inorganic material such as oxide, nitride, or the like.

A first gate metal pattern including a gate electrode GE may be disposed on the active pattern AP. A first insulation layer 230 may be disposed between the active pattern AP and the gate electrode GE.

A second gate metal pattern including a capacitor electrode pattern CE may be disposed on the gate electrode GE. The second gate metal pattern may further include a wiring for transferring various signals or the like.

A second insulation layer 240 may be disposed between the gate electrode GE and the capacitor electrode pattern CE. A third insulation layer 250 may be disposed on the capacitor electrode pattern CE.

For example, the active pattern AP may include silicon or a metal oxide semiconductor. In an embodiment, the active pattern AP may include polycrystalline silicon (polysilicon), which may be doped with n-type impurities or p-type impurities.

In another embodiment or in another transistor that is not illustrated, an active pattern may include a metal oxide semiconductor. For example, the active pattern may include a two-component compound (ABₓ), a ternary compound (ABₓC_{y}) or a four-component compound (ABₓC_{y}D_{z}), which may contain indium (In), zinc (Zn), gallium (Ga), tin (Sn), titanium (Ti), aluminum (Al), hafnium (Hf), zirconium (Zr), or magnesium (Mg). For example, the active pattern may include zinc oxide (ZnOₓ), gallium oxide (GaOₓ), titanium oxide (TiOₓ), tin oxide (SnOₓ), indium oxide (InOₓ), indium-gallium oxide (IGO), indium-zinc oxide (IZO), indium tin oxide (ITO), gallium zinc oxide (GZO), zinc magnesium oxide (ZMO), zinc tin oxide (ZTO), zinc zirconium oxide (ZnZrₓO_{y}), indium-gallium-zinc oxide (IGZO), indium-zinc-tin oxide (IZTO), indium-gallium-hafnium oxide (IGHO), tin-aluminum-zinc oxide (TAZO), indium-gallium-tin oxide (IGTO) or the like.

The first insulation layer 230, the second insulation layer 240, and the third insulation layer 250 may each independently include silicon oxide, silicon nitride, silicon oxynitride, silicon carbide, or a combination thereof. The first insulation layer 230, the second insulation layer 240, and the third insulation layer 250 may each include an insulating metal oxide such as aluminum oxide, tantalum oxide, hafnium oxide, zirconium oxide, titanium oxide, or the like. For example, the first insulation layer 230, the second insulation layer 240, and the third insulation layer 250 may each have a single-layered structure or a multi-layered structure including silicon nitride and/or silicon oxide, respectively, or may have different structures from each other.

The gate electrode GE and the capacitor electrode pattern CE may include a metal, a metal alloy, a metal nitride, a conductive metal oxide, or the like. For example, the gate electrode GE and the capacitor electrode pattern CE may each independently include gold (Au), silver (Ag), aluminum (Al), copper (Cu), nickel (Ni), platinum (Pt), magnesium (Mg), chromium (Cr), tungsten (W), molybdenum (Mo), titanium (Ti), tantalum (Ta), or an alloy thereof, and may have a single-layered structure or a multi-layered structure including different metal layers.

A first source metal pattern may be disposed on the third insulation layer 250. The first source metal pattern may include a source pattern SE and a drain pattern DE, which electrically contact the active pattern AP. The source pattern SE and the drain pattern DE may pass through the insulation layers disposed thereunder to contact the active pattern AP, respectively.

The first source metal pattern may include a metal, a metal alloy, a metal nitride, a conductive metal oxide, or the like. For example, the first source metal pattern may include gold (Au), silver (Ag), aluminum (Al), copper (Cu), nickel (Ni), platinum (Pt), magnesium (Mg), chromium (Cr), tungsten (W), molybdenum (Mo), titanium (Ti), tantalum (Ta), or an alloy thereof, and may have a single-layered structure or a multi-layered structure including different metal layers. In an embodiment, the first source metal pattern may have a multi-layered structure including an aluminum layer.

A fourth insulation layer 260 may be disposed on the first source metal pattern. The fourth insulation layer 260 may include an organic material. For example, the fourth insulation layer 260 may include an organic insulation material such as a phenol resin, an acryl resin, a polyimide resin, a polyamide resin, a siloxane resin, an epoxy resin, or the like.

An organic light-emitting diode 280 may be disposed on the fourth insulation layer 260. The organic light-emitting diode 280 may include a first electrode 282 electrically contacting the drain pattern DE, an organic light-emitting layer 284 disposed on the first electrode 282, and a second electrode 286 disposed on the organic light-emitting layer 284. The organic light-emitting layer 284 of the organic light-emitting diode 280 may be disposed at least in an opening of a pixel-defining layer 270 disposed on the fourth insulation layer 260. The first electrode 282 may be a lower electrode of the organic light-emitting diode 280, and the second electrode 286 may be an upper electrode of the organic light-emitting diode 280.

The first electrode 282 may function as an anode. For example, the first electrode 282 may be formed as a transmissive electrode or a reflecting electrode according to an emission type of the display device. When the first electrode 282 is a transmissive electrode, the first electrode 282 may include indium tin oxide, indium zinc oxide, zinc tin oxide, indium oxide, zinc oxide, tin oxide, or the like. When the first electrode 282 is a reflecting electrode, the first electrode 282 may include gold (Au), silver (Ag), aluminum (Al), copper (Cu), nickel (Ni), platinum (Pt), magnesium (Mg), chromium (Cr), tungsten (W), molybdenum (Mo), titanium (Ti), or a combination thereof, and may have a stacked structure further including the material that may be used for the transmissive electrode.

The pixel-defining layer 270 may have the opening overlapping at least a portion of the first electrode 282. For example, the pixel-defining layer 270 may include an organic insulating material.

The organic light-emitting layer 284 may include at least a light-emitting layer, and may further include at least one of a hole injection layer (HIL), a hole transporting layer (HTL), an electron transporting layer (ETL), and an electron injection layer (EIL). For example, the organic light-emitting layer 284 may include a low molecular weight organic compound or a high molecular weight organic compound.

In an embodiment, the organic light-emitting layer 284 may emit a red light, a green light, or a blue light. In another embodiment, the organic light-emitting layer 284 may emit a white light. The organic light-emitting layer 284 emitting a white light may have a multi-layer structure including a red-emitting layer, a green-emitting layer, and a blue-emitting layer, or it may have a single-layer structure including a mixture of a red-emitting material, a green-emitting material, and a blue-emitting material.

The second electrode 286 may be formed as a transmissive electrode or a reflecting electrode according to an emission type of the display device. For example, the second electrode 286 may include a metal, a metal alloy, a metal nitride, a metal fluoride, a conductive metal oxide, or a combination thereof.

For example, the second electrode 286 and at least one layer of the organic light-emitting layer 284 may be formed as a common layer extending continuously over pixels in a display area. However, embodiments are not limited thereto. For example, the organic light-emitting layer 284 may be formed as patterns corresponding to a pixel area and separated from each other.

An encapsulation layer 290 may be disposed on the organic light-emitting diode 280. The encapsulation layer 290 may have a stacked structure of an inorganic thin film and an organic thin film. For example, the encapsulation layer 290 may include a first inorganic thin film 292, an organic thin film 294 disposed on the first inorganic thin film 292 and a second inorganic thin film 296 disposed on the organic thin film 294. However, embodiments are not limited thereto. For example, the encapsulation layer 290 may include at least two organic thin films and at least three inorganic thin films.

A touch-sensing part TP may be disposed on the encapsulation layer 290. For example, the touch-sensing part TP may sense an external input by detecting a variation of a capacitance, thereby obtaining coordinate information of the external input. However, embodiments are not limited thereto. A touch-sensing part may sense an external input by detecting a pressure.

For example, the touch-sensing part TP may include a lower touch insulation layer 212, a sensing conductive pattern 214 and a protective layer 216.

The sensing conductive pattern 214 may include first sensing electrodes, which are arranged in a first direction, and second sensing electrodes, which are arranged in a second direction perpendicular to the first direction. For example, the first sensing electrodes may be electrically connected to each other by a connection portion disposed in a same layer as the first sensing electrodes. The second sensing electrodes may be electrically connected to each other by a bridge pattern disposed in a different layer from the second sensing electrodes.

The lower touch insulation layer 212 and the protective layer 216 may each independently include an inorganic insulating material. For example, the lower touch insulation layer 212 and the protective layer 216 may each independently include silicon oxide, silicon nitride, silicon oxynitride, silicon carbide, or a combination thereof. The lower touch insulation layer 212 and the protective layer 216 may each independently include an insulating metal oxide such as aluminum oxide, tantalum oxide, hafnium oxide, zirconium oxide, titanium oxide, or the like.

The sensing conductive pattern 214 may include a conductive material. For example, the sensing conductive pattern 214 may include a metal, a conductive metal oxide, a conductive polymer, graphene, carbon nano tube, or a combination thereof. For example, the metal may include molybdenum, silver, titanium, copper, aluminum, or an alloy thereof. For example, the metal may be provided to have a shape of a continuous thin film or a nano wire. For example, the conductive metal oxide may include indium tin oxide, indium zinc oxide, zinc tin oxide, indium oxide, zinc oxide, tin oxide, or a combination thereof. The sensing conductive pattern 214 may have a single-layer structure or a multi-layered structure including different materials.

The bridge pattern may include a same material as or a different material from the sensing conductive pattern 214.

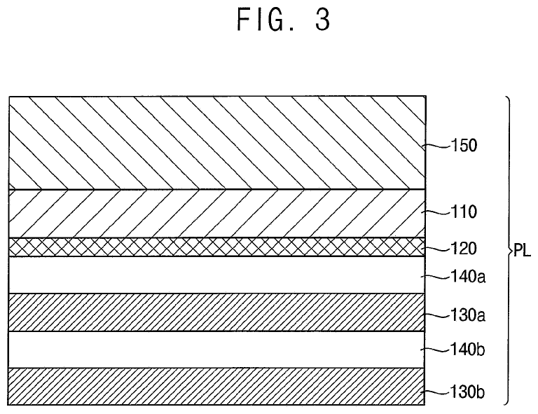

FIG. 3 is a schematic cross-sectional view illustrating an optical film according to an embodiment.

Referring to FIG. 3, the optical film PL according to an embodiment may include a polarizing layer 110, a protective layer 150, an inorganic barrier layer 120, a first phase-retardation layer 130a, a second phase-retardation layer 130b, a first adhesive layer 140a and a second adhesive layer 140b.

The polarizing layer 110 may function as a polarizer, which converts an incident light into a linearly polarized light. For example, the polarizing layer 110 may be obtained from dyeing a polymer film including polyvinyl alcohol (PVA) or the like, for example, with iodine, and stretching (e.g., drawing) the dyed film. In an embodiment, the polarizing layer 110 may further include boric acid, humidity, or the like.

The first phase-retardation layer 130a and the second phase-retardation layer 130b may each function as a circular polarizer, which converts the linearly polarized light into a circularly polarized light (including an elliptic polarized light). For example, the first phase-retardation layer 130a and the second phase-retardation layer 130b may each independently function as a half-wave plate or as a quarter-wave plate.

In an embodiment, at least one of the first phase-retardation layer 130a and the second phase-retardation layer 130b may each independently include cyclo-olefin polymer, polyacrylate, polycarbonate (PC), polystyrene (PSt), polyethylene terephthalate (PET), cellulose-based polymer, liquid crystal molecule, or a combination thereof. For example, the first phase-retardation layer 130a may include cyclo-olefin polymer, and the second phase-retardation layer 130b may include polyacrylate. In another embodiment, the first and second phase-retardation layers 130a and 130b may include a same material.

For example, the first phase-retardation layer 130a may include a positively birefringent material that has a slow axis representing a maximum refractive coefficient in a stretching direction. For example, the first phase-retardation layer 130a may include at least one of a cyclo-olefin polymer, PC, PET, and a cellulose-based polymer. In an embodiment, an unstretched film including a positively birefringent material may be prepared and rolled to form a rolled film. The rolled film may be unrolled and proceeded. The proceeded film may be stretched substantially in a direction oblique to a proceeding direction, and may be rolled again to form a roll of the first phase-retardation layer 130a having an oblique slow axis (optical axis).

For example, the second phase-retardation layer 130b may include a negatively birefringent material that has a slow axis representing a maximum refractive coefficient in a direction substantially perpendicular to a stretching direction. For example, the second phase-retardation layer 130b may include at least one of PSt, polyacrylate, PC, and acrylate-styrene copolymer. In an embodiment, an unstretched film including a negatively birefringent material may be prepared and rolled to form a rolled film. The rolled film may be unrolled and proceeded. The proceeded film may be stretched in a direction substantially perpendicular to a proceeding direction, and may be rolled again to form a roll of the second phase-retardation layer 130b having a slow axis substantially parallel to the proceeding direction of the proceeded film.

The protective layer 150 may be disposed on the polarizing layer 110 to protect the polarizing layer 110. For example, the protective layer 150 may be combined with the polarizing layer 110.

For example, the protective layer 150 may include polymethylmethacrylate (PMMA), triacetylcellulose (TAC), cyclo-olefin polymer, PET, or a combination thereof. In an embodiment, the protective layer 150 may include TAC.

The first adhesive layer 140a may combine the first phase-retardation layer 130a with the polarizing layer 110. The second adhesive layer 140b may combine the first phase-retardation layer 130a with the second phase-retardation layer 130b. For example, the first adhesive layer 140a may be disposed between the inorganic barrier layer 120, which may be directly disposed on a surface of the polarizing layer 110, and the first phase-retardation layer 130a. For example, the inorganic barrier layer 120 may be directly combined with a surface of the polarizing layer 110 and the first phase-retardation layer 130a.

For example, the first adhesive layer 140a and the second adhesive layer 140b may each independently include an acrylic adhesive, a UV glue, a PVA-based adhesive, or the like. In an embodiment, the first adhesive layer 140a and the second adhesive layer 140b may each include a UV glue. The first and second adhesive layers 140a and 140b formed from the UV glue may have a smaller thickness and a greater durability against an external force such as a bending force.

In an embodiment, the first adhesive layer 140a may include a silane coupling agent and an adhesive binder to increase adhesion to the inorganic barrier layer 120.

The inorganic barrier layer 120 may block migration of ions from the polarizing layer 110.

The inorganic barrier layer 120 may include a non-polar inorganic material. For example, the inorganic barrier layer 120 may include NaF, Na₃AlF₃, LiF, MgF₂, CaF₂, BaF₂, BaF₂, SiO₂, LaF₃, CeF, Al₂O₃, ZrOₓ (zirconium oxide), NbOₓ (niobium oxide), ATO (antimony tin oxide), SiNₓ (silicon nitride), or a combination thereof.

The inorganic barrier layer 120 may include a material, which has no birefringence, has a refractivity of about 1.5, has a light-transmittance greater than or equal to about 90%, and has a water vapor transmission rate (WVTR) equal to or less than about 100 g/day·m². In view of the above, the inorganic barrier layer 120 may include, for example, SiO₂.

A thickness of the inorganic barrier layer 120 may be equal to or less than about 5 μm, and a high thickness uniformity may be a desired quality, in order to prevent or reduce interference pattern. For example, a thickness of the inorganic barrier layer 120 may be in a range of about 0.1 μm to about 5 μm.

Iodine ions in the polarizing layer 110 may be dissolved by water, which is a polar solvent, under a condition with a high humidity. When iodine ions enter the panel part PN, a conductive pattern of the touch-sensing part TP may be corroded, thereby deteriorating reliability of the touch-sensing part.

The inorganic barrier layer 120 may block migration of the polar solvent or the ions dissolved by the polar solvent. Thus, iodine ions exiting from the polarizing layer 110 may be prevented from damaging a metal pattern of the panel part PN or the like.

In an embodiment, the inorganic barrier layer 120 may be formed by deposition. The inorganic barrier layer 120 may be formed directly on a surface of the polarizing layer 110 as illustrated in FIG. 3. Since a deposition process for forming the inorganic barrier layer 120 may be performed at a high temperature, the inorganic barrier layer 120 may contract as cooled. The optical film PL including the inorganic barrier layer 120 formed directly on the polarizing layer 110 may have increased reliability with compared to an optical film including an inorganic barrier layer formed directly on the first and second phase-retardation layers 130a and 130b. Thus, cracking of the inorganic barrier layer 120 may be reduced or prevented, and reliability of the polarizing film PL may be improved.

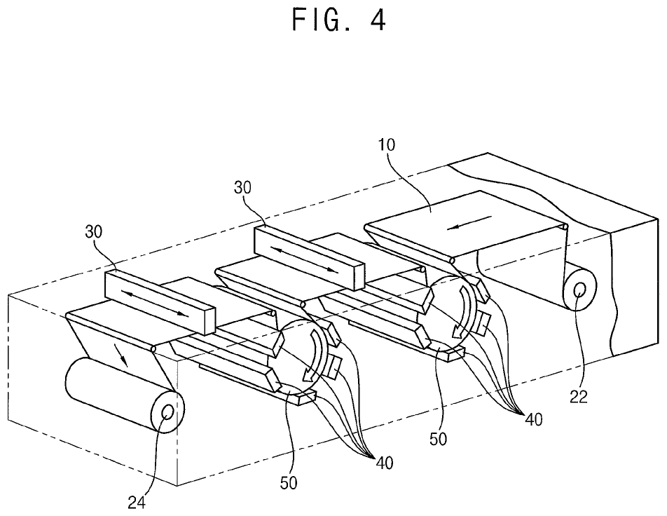

FIG. 4 is a perspective view illustrating a process of forming an optical film according to an embodiment.

An optical film according to an embodiment may include an inorganic barrier layer disposed on a polarizing layer. For example, the inorganic barrier layer may be combined with the polarizing layer. FIG. 4 may illustrate a process of forming the inorganic barrier layer on the polarizing layer.

In an embodiment, a roll-to-roll deposition apparatus may be used for forming the inorganic barrier layer on the polarizing layer.

In an embodiment, the roll-to-roll deposition apparatus may include a film-providing roller 22, a cooling drum 50, a deposition part 40, an inspection part 30 and a winding roller 24.

The film-providing roller 22 may provide a film 10. For example, the film 10 may be a polarizing layer. In another embodiment, the film 10 may include a polarizing layer and a protective layer disposed on the polarizing layer. For example, the film 10 may include a protective layer combined with a polarizing layer. In another embodiment, the film 10 may include a phase-retardation layer.

The cooling drum 50 may cool the film 10 to prevent the film 10 from being damaged by heat applied thereto in a deposition process. A cooling agent or the like may be provided to the cooling drum 50 so that the cooling drum 50 may cool the film 10. The cooling drum 50 may function as a stage supporting the film 10 in the deposition process.

The film 10 may be transported along a surface of the cooling drum 50, which may be an outer circumferential surface. The deposition part 40 may be disposed above the surface of the cooling drum 50. For example, deposition parts 40 may be disposed along the surface of the cooling drum 50. The film 10 may be disposed between the cooling drum 50 and the deposition part 40. The film 10 may contact the surface of the cooling drum 50, and may be transported by rotation of the cooling drum 50.

The deposition part 40 may provide a deposition source to the film 10 through sputtering, chemical vaporization deposition, or the like. As a result, the inorganic barrier layer may be formed on a surface of the film 10. In an embodiment, the deposition parts 40 may provide a same deposition source. In another embodiment, the deposition parts 40 may provide different deposition sources depending on a composition of the inorganic barrier layer.

A combination of the deposition part 40 and the cooling drum 50 may be suitably repeated depending on a desired thickness of the inorganic barrier layer.

The inspection part 30 may inspect defects of the inorganic barrier layer, or may measure a thickness of the inorganic barrier layer. Based on results of the inspection, a deposition condition may be adjusted, or products with defects may be identified.

The winding roller 24 may wind the film 10 with the inorganic barrier layer to form a film roll.

In an embodiment, the film 10 may be a polarizing layer. The polarizing layer disposed on the inorganic barrier layer may be disposed on a phase-retardation layer by an adhesive layer to form an optical film. For example, an optical film may be formed from a polarizing layer that is combined with an inorganic barrier layer and with a phase-retardation layer.

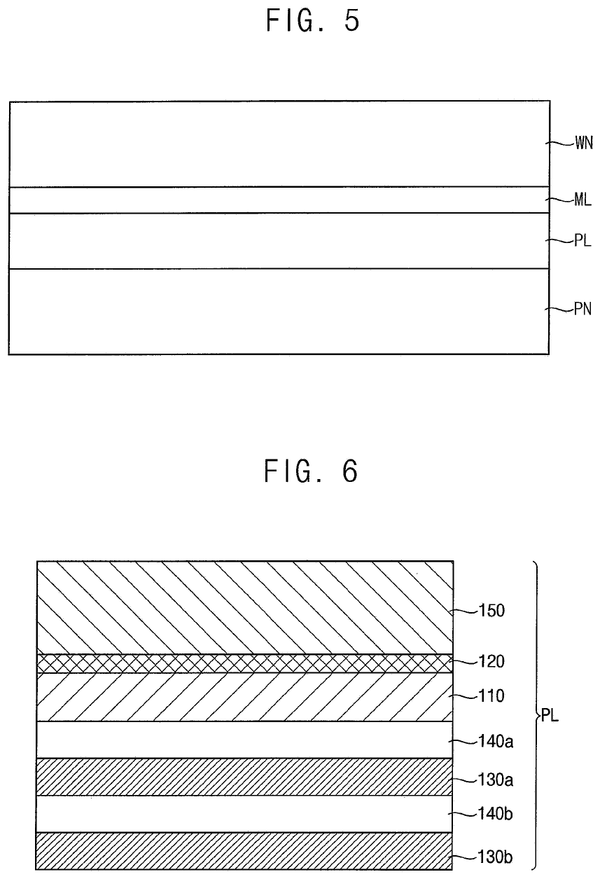

FIG. 5 is a schematic cross-sectional view illustrating a display device according to an embodiment.

Referring to FIG. 5, a display device includes a panel part PN, an optical film PL, a metallic functional layer ML and a protective window WN. The optical film PL may be disposed on an upper surface of the panel part PN. For example, the optical film PL may be combined with an upper surface of the panel part PN. The optical film PL may function as a polarizer.

The metallic functional layer ML may be disposed between the protective window WN and the optical film PL.

The metallic functional layer ML may include at least a metal layer. For example, the metallic functional layer ML may include a metal layer and an inorganic layer, may include a metal layer and an organic layer, or may include a metal layer, an inorganic layer, and an organic layer. In an embodiment, the metallic functional layer ML may include at least one of a fingerprint-sensing part, a pressure-sensing part, and an antenna.

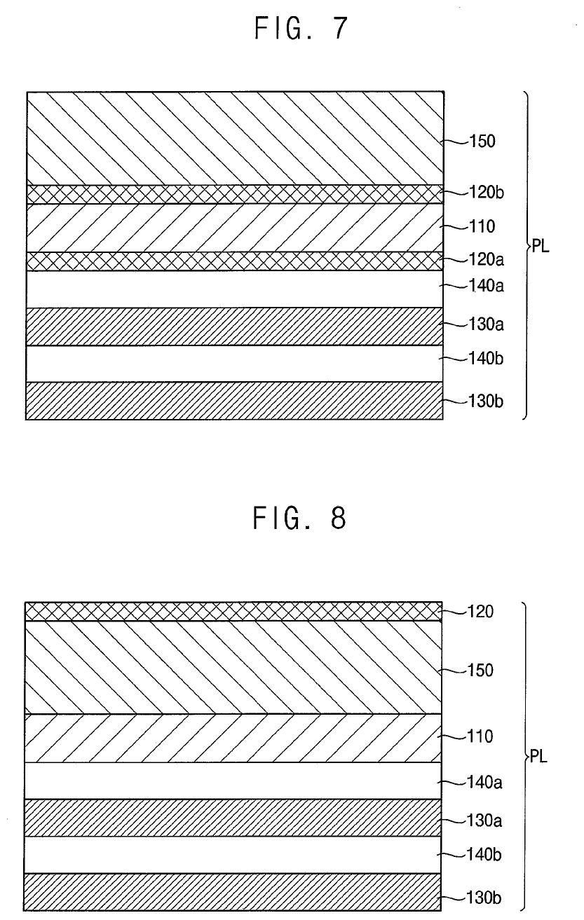

As illustrated in FIG. 5, when the metallic functional layer ML is disposed on the optical film PL, the optical film PL may have a suitable configuration to prevent an ion or a polar solvent in the optical film PL from entering the metallic functional layer ML. For example, the embodiments may be explained with reference to embodiments illustrated in FIGS. 6 to 8.

Referring to FIG. 6, an optical film PL according to an embodiment may include a polarizing layer 110, a protective layer 150, an inorganic barrier layer 120, a first phase-retardation layer 130a, a second phase-retardation layer 130b, a first adhesive layer 140a, and a second adhesive layer 140b.

In an embodiment, the inorganic barrier layer 120 may be disposed on an upper surface of the polarizing layer 110. For example, the inorganic barrier layer 120 may be combined with an upper surface of the polarizing layer 110. Thus, the inorganic barrier layer 120 may be disposed between the polarizing layer 110 and the protective layer 150. The optical film PL may prevent an ion or a polar solvent in the optical film PL from entering the metallic functional layer disposed on the optical film PL.

Referring to FIG. 7, an optical film PL according to an embodiment may include a polarizing layer 110, a protective layer 150, a first inorganic barrier layer 120a, a second inorganic barrier layer 120b, a first phase-retardation layer 130a, a second phase-retardation layer 130b, a first adhesive layer 140a, and a second adhesive layer 140b.

In an embodiment, the first inorganic barrier layer 120a may be disposed on a lower surface of the polarizing layer 110. For example, the first inorganic barrier layer 120a may be combined with a lower surface of the polarizing layer 110. The second inorganic barrier layer 120b may be disposed on an upper surface of the polarizing layer 110. For example, the second inorganic barrier layer 120b may be combined with an upper surface of the polarizing layer 110 Thus, the first inorganic barrier layer 120a is disposed between the polarizing layer 110 and the first adhesive layer 140a, and the second inorganic barrier layer 120b is disposed between the polarizing layer 110 and the protective layer 150.

The first and second inorganic barrier layers 120a and 120b may each prevent an ion or a polar solvent in the optical film PL from migrating in both directions.

Referring to FIG. 8, an optical film PL according to an embodiment may include a polarizing layer 110, a protective layer 150, an inorganic barrier layer 120, a first phase-retardation layer 130a, a second phase-retardation layer 130b, a first adhesive layer 140a and a second adhesive layer 140b.

In an embodiment, the protective layer 150 is disposed on the polarizing layer 110, and the inorganic barrier layer 120 is disposed on the protective layer 150. Thus, the optical film PL may prevent an ion or a polar solvent in the optical film PL from entering the metallic functional layer ML disposed on the optical film PL.

FIG. 9 is a schematic cross-sectional view illustrating an optical film according to an embodiment.

Referring to FIG. 9, an optical film PL according to an embodiment may include a polarizing layer 110, a protective layer 150, an inorganic barrier layer 120, a first phase-retardation layer 130a, a second phase-retardation layer 130b, a first adhesive layer 140a, and a second adhesive layer 140b.

In an embodiment, the inorganic barrier layer 120 may be disposed on at least one of the first and second phase-retardation layers 130a and 130b. For example, the inorganic barrier layer 120 may be disposed on the first phase-retardation layer 130a so that it may be disposed between the first phase-retardation layer 130a and the first adhesive layer 140a. For example, the inorganic barrier layer 120 may be combined with the first phase-retardation layer 130a.

For example, the inorganic barrier layer 120 may be formed by depositing an inorganic material on a film, which includes the first phase-retardation layer 130a, as illustrated in FIG. 4.

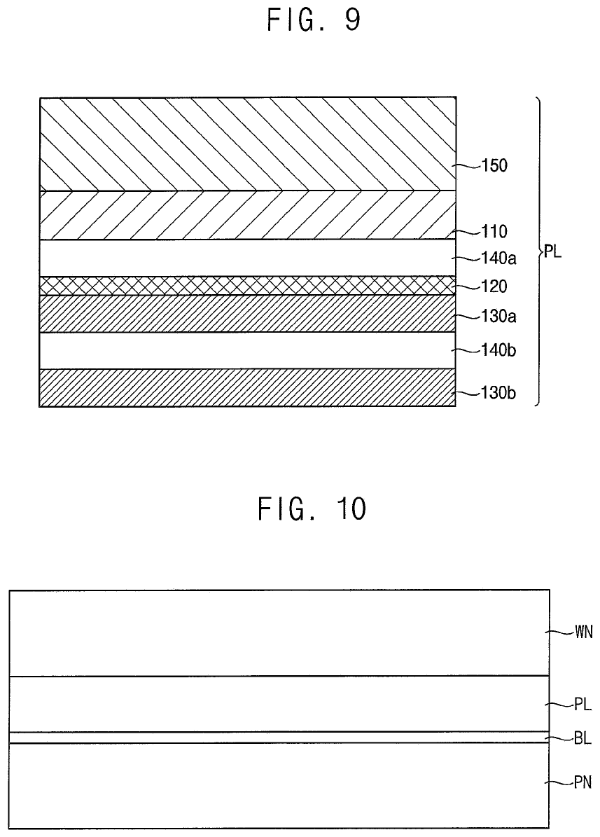

FIG. 10 is a schematic cross-sectional view illustrating a display device according to an embodiment.

Referring to FIG. 10, a display device includes a panel part PN, an optical film PL, and a protective window WN. The optical film PL may be disposed on an upper surface of the panel part PN. The upper surface of the panel part PN may be a light-exiting surface, through which a light generated in the panel part PN may exit outwardly. The protective window WN may be disposed on an upper surface of the optical film PL. For example, the protective window WN may be combined with an upper surface of the optical film PL. Thus, the optical film PL may be disposed between the panel part PN and the protective window WN.

The optical film PL may include a polarizing layer functioning as a polarizer. For example, the optical film PL may include a polarizing layer, a protective layer disposed on an upper surface of the polarizing layer, and at least one phase-retardation layer disposed on a lower surface of the polarizing layer. For example, in the optical film PL, the protective layer may be combined with an upper surface of the polarizing layer and the at least one phase-retardation layer may be combined with a lower surface of the polarizing layer. For example, the panel part PN may include a touch-sensing part as illustrated in FIG. 2.

The display device may include an inorganic barrier layer BL disposed between the optical film PL and the panel part PN. Thus, the inorganic barrier layer BL may be disposed between the polarizing layer of the optical film PL and the touch-sensing part of the panel part PN. For example, the inorganic barrier layer BL may be deposited on a lower surface of the optical film PL or on an upper surface of the touch-sensing part.

The inorganic barrier layer BL may prevent an ion or a polar solvent in the optical film PL from entering the touch-sensing part of the panel part PN.

The above embodiments provide an organic-light emitting display device. However, embodiments are not limited thereto. For example, embodiments may be applied for various display devices such as a liquid crystal display device, an electroluminescent display device, a micro LED display device, or the like.

Embodiments may be applied to various display devices. In an embodiment, for example, embodiments may be applied to vehicle-display device, a ship-display device, an aircraft-display device, portable communication devices, display devices for display or for information transfer, a medical-display device, etc.

The foregoing is illustrative of embodiments and is not to be construed as limiting thereof. Although embodiments have been described, those skilled in the art will readily appreciate that many modifications are possible in the embodiments without materially departing from the novel teachings and aspects of the inventive concept. Accordingly, all such modifications are intended to be included within the scope of the inventive concept. Therefore, it is to be understood that the foregoing is illustrative of various embodiments and is not to be construed as limited to the specific embodiments disclosed, and that modifications to the disclosed embodiments, as well as other embodiments, are intended to be included within the scope of the inventive concept, as set forth in the following claims and equivalents thereof.

What is claimed is:

1. An optical film comprising:
a polarizing layer including a polymer dyed with iodine;
a phase-retardation layer disposed under the polarizing layer; and
an inorganic barrier layer including a non-polar inorganic material, wherein
the inorganic barrier layer is disposed on at least a surface of the polarizing layer,
the inorganic barrier layer has a water vapor transmission rate (WVTR) equal to or less than about 100 g/day·m², and
the inorganic barrier layer has a thickness equal to or less than about 5 μm.

2. The optical film of claim 1, wherein the inorganic barrier layer includes at least one of NaF, Na₃AlF₃, LiF, MgF₂, CaF₂, BaF₂, BaF₂, SiO₂, LaF₃, CeF, Al₂O₃, ZrOₓ (zirconium oxide), NbOₓ (niobium oxide), ATO (antimony tin oxide), and SiNₓ (silicon nitride).

3. The optical film of claim 1, wherein the inorganic barrier layer includes SiO₂.

4. The optical film of claim 1, wherein the inorganic barrier layer is disposed between the polarizing layer and the phase-retardation layer.

5. The optical film of claim 1, further comprising a protective layer including at least one of polymethylmethacrylate, triacetylcellulose, cyclo-olefin polymer, and polyethylene terephthalate.

6. The optical film of claim 5, wherein the inorganic barrier layer is disposed between the polarizing layer and the protective layer.

7. The optical film of claim 5, wherein the inorganic barrier layer includes:
a first inorganic barrier layer disposed between the polarizing layer and the phase-retardation layer; and
a second inorganic barrier layer disposed between the polarizing layer and the protective layer.

8. The optical film of claim 1, further comprising an adhesive layer contacting the inorganic barrier layer, the adhesive layer including an adhesive binder and a silane coupling agent.

9. The optical film of claim 1, wherein the phase retardation layer includes:
a first phase retardation layer that is a half wave plate; and
a second phase retardation layer that is a quarter wave plate.

10. A display device comprising:
a panel part including a display panel; and
an optical film disposed on at least a surface of the panel part, the optical film including:
a polarizing layer including a polymer dyed with iodine;
a phase-retardation layer disposed under the polarizing layer; and
an inorganic barrier layer including a non-polar inorganic material, wherein
the inorganic barrier layer has a water vapor transmission rate (WVTR) equal to or less than about 100 g/day·m², and
the inorganic barrier layer has a thickness equal to or less than about 5 μm.

11. The display device of claim 10, wherein the inorganic barrier layer includes at least one of NaF, Na₃AlF₃, LiF, MgF₂, CaF₂, BaF₂, BaF₂, SiO₂, LaF₃, CeF, Al₂O₃, ZrOₓ (zirconium oxide), NbOₓ (niobium oxide), ATO (antimony tin oxide), and SiNₓ (silicon nitride).

12. The display device of claim 10, wherein the inorganic barrier layer includes SiO₂.

13. The display device of claim 10, wherein
the optical film further includes a protective layer disposed on the polarizing layer and including at least one of polymethylmethacrylate, triacetylcellulose, cyclo-olefin polymer, and polyethylene terephthalate, and
the inorganic barrier layer is disposed between the polarizing layer and the protective layer.

14. The display device of claim 13, wherein the inorganic barrier layer includes:
a first inorganic barrier layer disposed between the polarizing layer and the phase-retardation layer; and
a second inorganic barrier layer disposed between the polarizing layer and the protective layer.

15. The display device of claim 10, wherein the inorganic barrier layer is directly disposed on the polarizing layer.

16. The display device of claim 10, wherein the optical film further includes an adhesive layer contacting the inorganic barrier layer, the adhesive layer including an adhesive binder and a silane coupling agent.

17. The display device of claim 10, wherein the display panel includes a touch-sensing part.

18. The display device of claim 10, further comprising a protective window disposed on the optical film.

19. The display device of claim 18, further comprising a metallic functional layer disposed between the protective window and the optical film.

20. The display device of claim 19, wherein the metallic functional layer includes at least one of a fingerprint-sensing part, a pressure-sensing part, and an antenna.
